(19) United States
(12) Patent Application Publication
(10) Pub. No.: US 2005/0054182 A1
(43) Pub. Date: Mar. 10, 2005

(54) Method for suppressing boron penetration by implantation in P+ MOSFETS

(75) Inventor: Tzu Yu Wang, Hsinchu (TW)

Correspondence Address: Finnegan, Henderson, Farabow,;Garrett & Dunner, L.L.P., 1300 I Street, N.W., Washington, DC, 20005-3315, US

(73) Assignee: Macronix International Co., Ltd.

(21) Appl. No.: 10/656,224

(22) Filed: Sep. 8, 2003

(51) Int. Cl. H01L 21/8238; H01L 21/425

(52) U.S. Cl. 438/528

(57) ABSTRACT

A method for manufacturing a semiconductor device includes providing a first layer, forming a plurality of isolation regions in the first layer, forming an insulating layer over the first layer, forming a second layer over the insulating layer, implanting one of helium, neon, krypton or xenon ions into the second layer, implanting boron ions into the second layer, patterning and etching the implanted second layer and the insulating layer, annealing at least the layer of implanted second layer to activate the implanted boron ions, and forming source and drain regions in the first layer.

### FIELD OF THE INVENTION

The invention pertains in general to a method of manufacturing a semiconductor device, and more particularly, to a method of preventing undesired dopant diffusion in P-channel devices.

### BACKGROUND OF THE INVENTION

A CMOS (complementary metal oxide semiconductor) device generally includes both a p-channel MOS transistor and an n-channel MOS transistor. Efforts have been made in the last decade to reduce the channel length of CMOS devices, one reason being a reduced channel length translates into a reduction in device size, and correspondingly a reduction in the cost of the semiconductor product into which the CMOS devices are incorporated. However, a reduced channel length often produces an unintended and undesirable leakage current in the channel region. This is known as “short-channel effect.” One of the causes of short-channel effect is the presence of unintended impurities in the channel regions. For p-channel MOS transistors, boron ions are often the unintended impurities that contribute to the short-channel effect.

During the manufacturing process for a p-channel MOS transistor, a target layer, for example, a gate layer, is doped with dopant materials including arsenic and boron difluoride (BF₂). For certain manufacturing processes that require BF₂ as the dopant, the presence of fluorine ions during BF₂ implantation enhances the diffusion of boron ions. As a result, during the subsequent annealing process, some of the boron ions may diffuse through an insulating layer, such as a gate oxide, into the underlying layer, such as the silicon substrate. Such unintended boron penetration often results in undesired shift in the threshold voltage, increased electron trapping, and poor reliability in the p-channel devices.

Various techniques have been developed to solve the above-mentioned problems. One method implants nitrogen particles into the target layer before boron implantation to prevent boron ions from diffusing into the underlying layer. Another conventional method uses a stacked structure to compensate for the unintended boron diffusion. However, these conventional approaches still have certain drawbacks, such as increased complexity in the manufacturing processes.

### SUMMARY OF THE INVENTION

In accordance with the invention, there is provided a method for manufacturing a semiconductor device that includes providing a first layer, forming a plurality of isolation regions in the first layer, forming an insulating layer over the first layer, forming a second layer over the insulating layer, implanting one of helium, neon, krypton or xenon ions into the second layer, implanting boron ions into the second layer, patterning and etching the implanted second layer and the insulating layer, annealing at least the layer of implanted second layer to activate the implanted boron ions, and forming source and drain regions in the first layer.

Also in accordance with the present invention, there is provided a method for suppressing boron penetration of a gate oxide during the manufacture of an integrated circuit that includes providing a substrate, forming a plurality of isolation regions, forming a layer of gate oxide over the substrate, depositing a layer of silicon material over the layer of gate oxide, implanting boron ions into the silicon material layer to form an implanted silicon layer, implanting one of helium, neon, krypton or xenon ions into the implanted silicon layer to create a strain between particles of the silicon layer and implanted helium, neon, krypton or xenon ions, patterning the implanted silicon layer and the layer of gate oxide, activating the implanted boron ions, and forming source and drain regions in the substrate.

In accordance with the present invention, there is additionally provided a method for manufacturing a semiconductor device that includes comprising providing a substrate, forming a plurality of isolation regions, forming a layer of gate oxide over the substrate, forming a layer of semiconducting material over the layer of gate oxide, implanting boron ions into the layer of semiconducting material, creating a barrier in the layer of semiconducting material to prevent implanted boron ions from diffusing into the substrate, patterning and etching the implanted silicon layer and the layer of gate oxide, annealing at least the layer of semiconducting material, and forming source and drain regions in the substrate.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate one embodiment of the invention and together with the description, serve to explain the principles of the invention.

### BRIEF DESCRIPTION OF THE DRAWINGS

FIGS. 1A-1D are cross-sectional views of the structure formed with one embodiment of the method of the present invention.

### DESCRIPTION OF THE EMBODIMENTS

Reference will now be made in detail to the present embodiments of the invention, examples of which are illustrated in the accompanying drawings. Wherever possible, the same reference numbers will be used throughout the drawings to refer to the same or like parts.

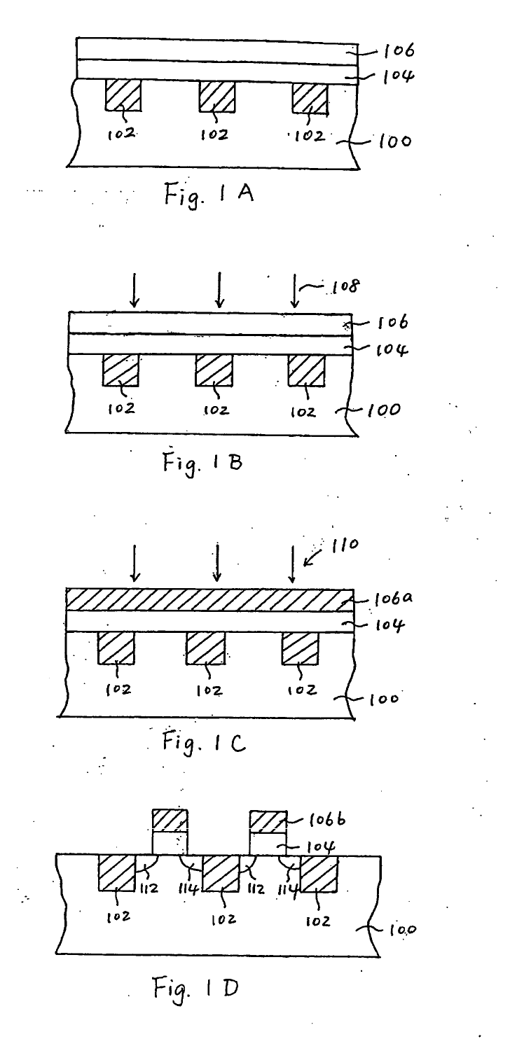

FIGS. 1A-1D are cross-sectional views of a structure formed with a method consistent with one embodiment of the present invention. Referring to FIG. 1A, the method of the present invention commences with providing a silicon substrate 100 and forming a plurality of isolation regions 102 between active areas (not shown) in substrate 100. Conventional techniques for insulating individual devices, such as local oxidation of silicon (LOCOS) and shallow trench isolation (STI), may be used to create isolation regions 102. Next, a gate oxide layer 104 is formed over substrate 100 and isolation regions 102 to a suitable thickness. Gate oxide layer 104 may be grown or deposited over substrate 100 with any conventional method. A layer of semiconducting material 106, such as silicon, gallium or a combination thereof, is deposited over gate oxide 104.

Referring to FIG. 1B, a first ion implantation process follows by doping layer 106 with a first dopant 108. Dopant 108 may be ions selected from one of the inert gases helium (He), neon (Ne), krypton (Kr), or xenon (Xe). The first implantation is performed with a doping density of at least 10¹³ ions/cm² and at energy of less than 100 KeV. Referring to FIG. 1C, a second ion implantation follows, in which first-doped layer 106a is further implanted with boron (B) or boron difluoride (BF₂) ions 110 to form a conductive layer 106a. The boron (B) or boron difluoride (BF₂) implantation is performed with a doping density of at least 1013 ions/cm² and at energy of less than approximately 80 KeV.

Because the particles of layer 106 and those of first dopant 108 are different in size, a strain is created between these particles. The strain, in turn, acts as a barrier to prevent implanted boron ions from diffusing through gate oxide layer 104 and into substrate 100 during the subsequent annealing process. In one embodiment, boron (B) or boron difluoride (BF₂) ions 110 are implanted into layer 106, followed by the implantation of first dopant 108 into layer 106.

Referring to FIG. 1D, layer 106b and gate oxide layer 104 are patterned and etched to form a plurality of gate structures (not numbered) with conventional processes. The plurality of gate structures are insulated by isolation regions 102. Thereafter, an annealing step is performed to activate the implanted boron (B) or boron difluoride (BF₂) ions in the implanted region 106b. Finally, source and drain regions 112 and 114 are formed in substrate 100

Although the embodiments described above relate to the prevention of boron ions from diffusing into the substrate through a gate oxide layer, the method of the present invention is equally applicable to preventing boron ions from diffusing into any underlying layer through an insulating layer disposed therebetween. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method for manufacturing a semiconductor device, comprising:
providing a first layer;
forming a plurality of isolation regions in the first layer;
forming an insulating layer over the first layer;
forming a second layer over the insulating layer;
implanting one of helium, neon, krypton or xenon ions into the second layer;
implanting boron ions into the second layer;
patterning and etching the implanted second layer and the insulating layer;
annealing at least the layer of implanted second layer to activate the implanted boron ions; and
forming source and drain regions in the first layer.

2. The method of claim 1, wherein the first layer comprises a substrate.

3. The method of claim 1, wherein the insulating layer comprises a gate oxide layer.

4. The method of claim 1, wherein the dosage of one of helium, neon, krypton or xenon ions is higher than 10¹³ ions per cm².

5. The method of claim 1, wherein the step of implanting one of helium, neon, krypton or xenon ions is performed at energy of less than 100 KeV.

6. The method of claim 1, wherein the second layer comprises one of silicon, gallium, or a combination thereof.

7. The method of claim 1, wherein the plurality of isolation regions are formed by using a local oxidation of silicon process.

8. The method of claim 1, wherein the plurality of isolation regions are formed by using a shallow trench isolation process.

9. The method of claim 1, wherein the dosage of the boron ions is at least 10¹³ ions per cm².

10. The method of claim 1, wherein the step of implanting the boron ions is performed at energy of less than approximately 80 KeV.

11. A method for suppressing boron penetration of a gate oxide during the manufacture of an integrated circuit, comprising:
providing a substrate;
forming a plurality of isolation regions;
forming a layer of gate oxide over the substrate;
deposition a layer of silicon material over the layer of gate oxide;
implanting boron ions into the silicon material layer to form an implanted silicon layer;
implanting one of helium, neon, krypton or xenon ions into the implanted silicon layer to create a strain between particles of the silicon layer and implanted helium, neon, krypton or xenon ions;
patterning the implanted silicon layer and the layer of gate oxide;
activating the implanted boron ions; and
forming source and drain regions in the substrate.

12. The method of claim 11, wherein the dosage of helium, neon, krypton or xenon ions is higher than 10¹³ ions per cm².

13. The method of claim 11, wherein the plurality of isolation regions are formed by using a local oxidation of silicon process.

14. The method of claim 11, wherein the plurality of isolation regions are formed by using a shallow trench isolation process.

15. The method of claim 11, wherein the step of implanting one of helium, neon, krypton or xenon ions is performed at energy of less than 100 KeV.

16. The method of claim 11, wherein the dosage of the boron ions is at least 10¹³ ions per cm².

17. The method of claim 11, wherein the step of implanting the boron ions is performed at energy of less than approximately 80 KeV.

18. A method for manufacturing a semiconductor device, comprising:
providing a substrate;
forming a plurality of isolation regions;
forming a layer of gate oxide over the substrate;
forming a layer of semiconducting material over the layer of gate oxide;
implanting boron ions into the layer of semiconducting material;
creating a barrier in the layer of semiconducting material to prevent implanted boron ions from diffusing into the substrate;
patterning and etching the implanted silicon layer and the layer of gate oxide;
annealing at least the layer of semiconducting material; and
forming source and drain regions in the substrate.

19. The method of claim 18, wherein the step of creating a barrier in the layer of semiconducting material comprises implanting one of helium, neon, krypton or xenon ions into the layer of semiconducting material.

20. The method of claim 18, wherein the dosage of one of helium, neon, krypton or xenon ions is higher than 10¹³ ions per cm².

21. The method of claim 18, wherein the step of implanting one of helium, neon, krypton or xenon ions is performed at energy of less than 100 KeV.

22. The method of claim 18, wherein the layer of semiconducting material comprises one of silicon, gallium, or a combination thereof.

23. The method of claim 18, wherein the dosage of the boron ions is at least 10¹³ ions per cm².

24. The method of claim 18, wherein the step of implanting the boron ions is performed at energy of less than approximately 80 KeV.
